(19) United States
(12) Patent Application Publication
(10) Pub. No.: US 2019/0103418 A1
(43) Pub. Date: Apr. 4, 2019

(54) ARRAY SUBSTRATE AND METHOD FOR MANUFACTURING THEREOF, AND DISPLAY DEVICE

(71) Applicant: Shenzhen China Star Optoelectronics Technology Co. Ltd, Shenzhen, Guangdong (CN)

(72) Inventor: Baixiang HAN, Shenzhen, Guangdong (CN)

(73) Assignee: Shenzhen China Star Optoelectronics Technology Co. , Ltd., Shenzhen, Guangdong (CN)

(21) Appl. No.: 15/536,916

(22) PCT Filed: May 25, 2017
(86) PCT No.: PCT/CN2017/085870

§ 371 Date: Jun. 16, 2017

(30) Foreign Application Priority Data
Apr. 24, 2017 (CN) 201710271282.2

(51) Int. Cl. H01L 27/12; H01L 27/32; H01L 51/52

(52) U.S. Cl. CPC H01L 27/1218; H01L 27/3246; H01L 27/1262; H01L 51/5221; H01L 51/5206; H01L 27/3262

(57) ABSTRACT

The present invention discloses an array substrate and a method for manufacturing thereof, and a display device, wherein the method comprises: preparing a laminated structure and an anodic layer on a substrate sequentially; preparing a photoresist layer with a receiving cavity and a concave structure on the laminated structure and the anode layer; preparing an organic light emitting device in the receiving cavity; and preparing a reflective cathode layer on the organic light emitting device and the photoresist layer. By the above-described manner, the present invention can avoid the light leakage phenomenon caused by the reflective cathode layer and enhance panel display quality.

### FIELD OF THE INVENTION

The present disclosure related to a field of display technology, especially related to an array substrate and a method for manufacturing thereof, and a display device.

### BACKGROUND OF THE INVENTION

A method of color a traditional bottom emission Active-Matrix Organic Light Emitting Diode (AMOLED) is usually achieved by stacks of White Organic Light Emitting Diode (WOLED) and Color Filter (CF), or achieved by RGB mode.

Wherein, since the whole surface of a bottom emission cathode material evaporation and high reflectivity, a traditional pixel design is affected by a cathode reflection and produces different degrees of light leakage phenomenon, and reduces panel display quality.

### SUMMARY OF THE INVENTION

The present disclosure provides an array substrate and a method for manufacturing thereof, and a display device. It is able to prevent light leakage phenomenon caused by a reflective cathode layer and enhance panel display quality.

To solve the above technical problem, an aspect of the present disclosure is: providing a display device comprises an array substrate, the array substrate comprises: a substrate; a laminated structure, disposed on the substrate; an anode layer, disposed on the laminated structure; a photoresist layer, deposited on the anode layer and the laminated structure, the photoresist layer comprises a receiving cavity and a concave structure; an organic light emitting device, disposed within the receiving cavity; and a reflective cathode layer, deposited on the organic light emitting device and the photoresist layer. Wherein the laminated structure comprises a plurality of thin film transistors and a planarization layer; the photoresist layer comprises a pixel definition layer and a supporting layer.

To solve the above technical problem, an aspect of the present disclosure is: providing another method for manufacturing the array substrate, the method comprises: preparing the laminated structure and the anode layer on the substrate sequentially; preparing the photoresist layer with the receiving cavity and the concave structure on the laminated structure and the anode layer; preparing the organic light emitting device in the receiving cavity; and preparing a reflective cathode layer on the organic light emitting device and the photoresist layer.

To solve the above technical problem, still another aspect of the present disclosure is: providing the array substrate comprises: the substrate; the laminated structure, disposed on the substrate; the anode layer, disposed on the laminated structure; the photoresist layer, deposited on the anode layer and the laminated structure comprises the receiving cavity and the concave structure; the organic light emitting device, disposed within the receiving cavity; and the reflective cathode layer, deposited on the organic light emitting device and the photoresist layer.

The beneficial effects of the present disclosure are: apart from the current technologies, the present disclosure provides a method of manufacturing a concave structure on a photoresist layer, and it can reflect the light from the reflective cathode layer back to the light emitting direction and attenuate; to avoid light leakage phenomenon caused by the reflective cathode layer and enhance panel display quality.

### BRIEF DESCRIPTION OF THE DRAWINGS

FIG. 1 is a schematic flow diagram showing an embodiment of an array substrate manufacturing method of the present disclosure.

FIG. 2 is a schematic flow diagram showing an embodiment of step S1 in FIG. 1.

FIG. 3 is a schematic low diagram showing an embodiment of step S2 in FIG. 1.

FIG. 4 is a schematic flow diagram showing an embodiment of step S21 in FIG. 3.

FIG. 5 is a schematic flow diagram showing an embodiment of step S22 in FIG. 3.

FIG. 6 is a schematic flow diagram showing an embodiment of step S2 in FIG. 1.

FIG. 7 is a schematic flow diagram showing an embodiment of step S21a in FIG. 6.

FIG. 8 is a schematic flow diagram showing an embodiment of step S22a in FIG. 6.

FIG. 9 is a schematic structure diagram showing an embodiment of an array substrate of the present disclosure.

FIG. 10 is a schematic structure diagram showing an embodiment of a laminated structure in the array substrate of the present disclosure.

FIG. 11 is a schematic structure diagram showing another embodiment of the array substrate of the present disclosure.

FIG. 12 is a schematic structure diagram showing an embodiment of a display device of the present disclosure.

### DETAILED DESCRIPTION OF PREFERRED EMBODIMENTS

The following with the present disclosure that reference implementation, carried a clear example of the technical solutions of the present disclosure, a complete description, it is clear that the described embodiments are merely part of the embodiments of the present disclosure, but not all embodiments example. Based on the embodiments of the present disclosure, those of ordinary skill in not making all other embodiments without creative efforts obtained, are within the scope of the present disclosure is protected.

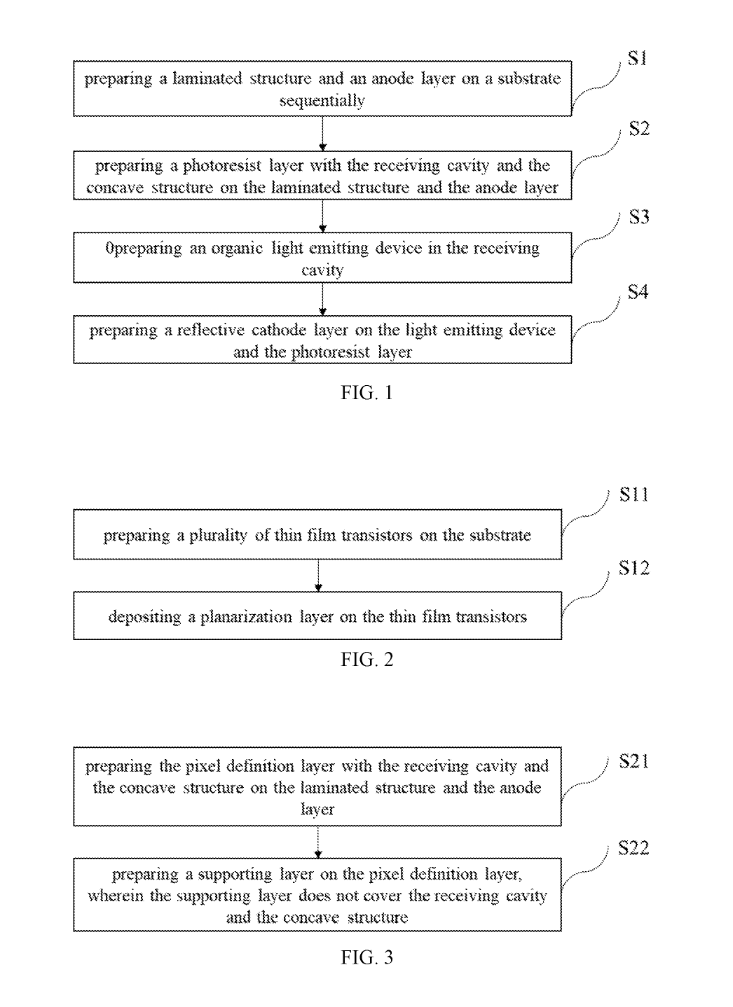

Referring to FIG. 1, FIG. 1 is a schematic flow diagram showing an embodiment of an array substrate manufacturing method of the present disclosure comprises the steps of:

Step S1, preparing a laminated structure and an anode layer on a substrate sequentially.

Wherein the substrate can be a transparent material, particularly can be any type of substrate such as glass, ceramic substrate or transparent plastic and so on, the present disclosure is not specifically limited thereto.

As shown in FIG. 2, step S1 further comprises the following sub-steps of:

S11, preparing a plurality of thin film transistors on the substrate.

Wherein each of the thin film transistors comprises a gate electrode layer, a gate insulating layer, a source electrode layer, a drain electrode layer, and a semiconductor oxide layer.

By depositing the gate electrode layer on the substrate, through the procedures of photoresist coating, exposure, development, etching, photoresist peeling, etc., to form the gate electrode layer with a predetermined pattern. After the gate electrode layer is formed, the gate insulating layer (GI) can be deposited on the substrate by chemical vapor deposition (CVD) and a yellow light etching process, wherein the GI can be silicon oxide (SiO2) film layer or silicon nitride (SiNx) film layer, or a laminate of silicon oxide (SiO2) and silicon nitride (SiNx), the present disclosure is not specific limited thereto. After forming the GI, depositing the source electrode layer and the drain electrode layer on the GI. Wherein the gate electrode layer, the source electrode layer, and the drain electrode layer can be materials such as Tungsten, Titanium, Cobalt, and Nickel and so on, and the present disclosure is not particularly limited. After forming the source electrode layer and the drain electrode layer, a layer of semiconductor oxide layer (IGZO) is coated on the source electrode layer, the drain electrode layer and the GI. Through the procedures of photoresist coating, exposure, development, etching, photoresist peeling and so on to form the semiconductor oxide layer with a predetermined pattern. In the present embodiment, the semiconductor oxide layer is used as the channel material, and other materials can be adopted in other embodiments.

S12, depositing a planarization layer on the thin film transistors.

Depositing a passivation layer (PAS) and the planarization layer (PLN) on the semiconductor oxide layer sequentially. After forming the PLN, preparing an anode layer (ITO) on the PLN by magnetron sputtering method, wherein the ITO is a N-type wide bandgap semiconductor with high light transmittance and conductivity. Of course, the laminated structure of the array substrate in the present embodiment is merely a simple example and is not limited thereto.

S2, preparing a photoresist layer with the receiving cavity and the concave structure on the laminated structure and the anode layer.

As shown in FIG. 3, step S2 further comprises the following sub-steps of:

S21, preparing the pixel definition layer with the receiving cavity and the concave structure on the laminated structure and the anode layer.

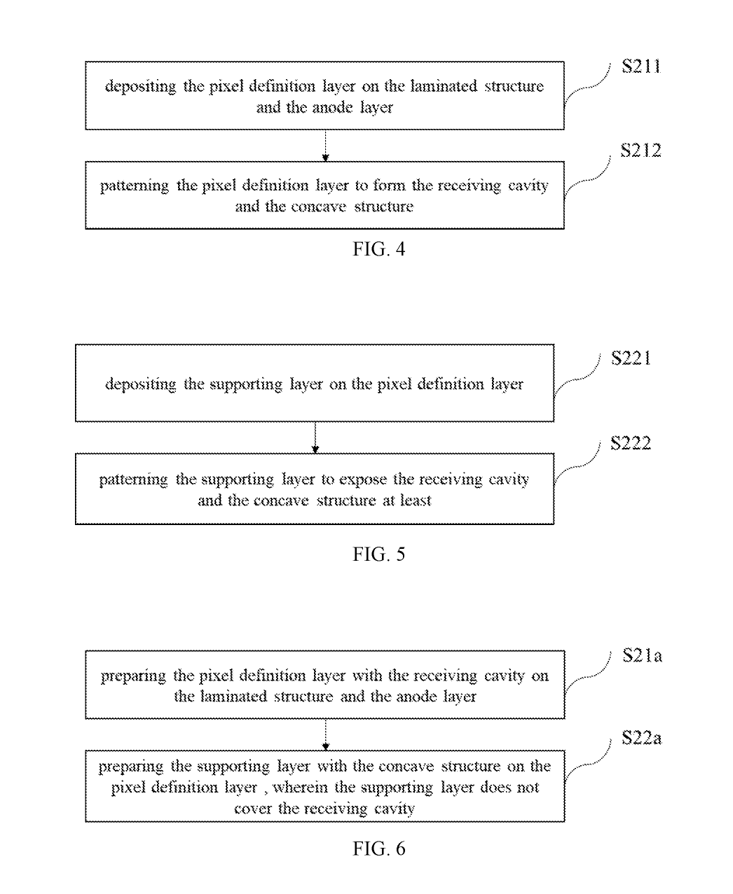

As shown in FIG. 4, step S21 further comprises the following sub-steps of:

S211, depositing the pixel definition layer on the laminated structure and the anode layer.

Wherein the pixel definition layer (PDL) is an organic photoresist layer.

S212, patterning the PDL to form the receiving cavity and the concave structure.

In step S212, patterning the PDL by yellow process. Wherein, the yellow process refers to a photosensitive material coated on the surface of the substrate, after exposure and developing process to leave the bottom portion of the protective effect, and then etching and stripping to get a permanent pattern. And in step S212, the operations of pre-baking, exposure, development, curing, etc., in the yellow process are used for the PDL, to form a PDL with the receiving cavity and the concave structure, and another purpose of the patterning is to expose the anode layer, which is disposed on the receiving cavity structure.

Wherein the concave structure can include but not limited to an arc, a circle, etc., and each of the concave structures is disposed between two adjacent receiving cavities. It should be noted that the formation of the receiving cavity and the concave structure eliminates the need for additional process and simplifies the operation.

S22, preparing a supporting layer on the pixel definition layer, wherein the supporting layer does not cover the receiving cavity and the concave structure.

As shown in FIG. 5, step S22 further comprises the following sub-steps of:

S221, depositing the supporting layer on the PDL.

After forming the PDL with the receiving cavity and the concave structure, the supporting layer (PS) is deposited on the PDL, and the supporting layer can also be an organic photoresist layer.

S222, patterning the supporting layer to expose the receiving cavity and the concave structure at least.

Similarly, further patterning the supporting layer. Particularly, the operations of pre-baking, exposure, development, curing, etc., in the yellow process are used for the supporting layer, so that the supporting layer exposes at least the receiving cavity and the concave structure.

In other embodiments, step S2 can further comprise the following sub-steps of:

As shown in FIG. 6, the embodiment differs from the embodiment in FIG. 3 is, in the embodiment shown in FIG. 3, patterning the PDL to form the receiving cavity and the concave structure; when the supporting layer is subjected to a patterning process, the supporting layer is subjected to the same patterning process by yellow process at the concave structure corresponding to the PDL, so that the concave structure is exposed. In the present embodiment, when patterning the PDL, only the receiving cavity is formed, and patterning the supporting layer by yellow process to form the supporting layer with concave structure. Particularly described as follows:

S21a, preparing the PDL with the receiving cavity on the laminated structure and the anode layer.

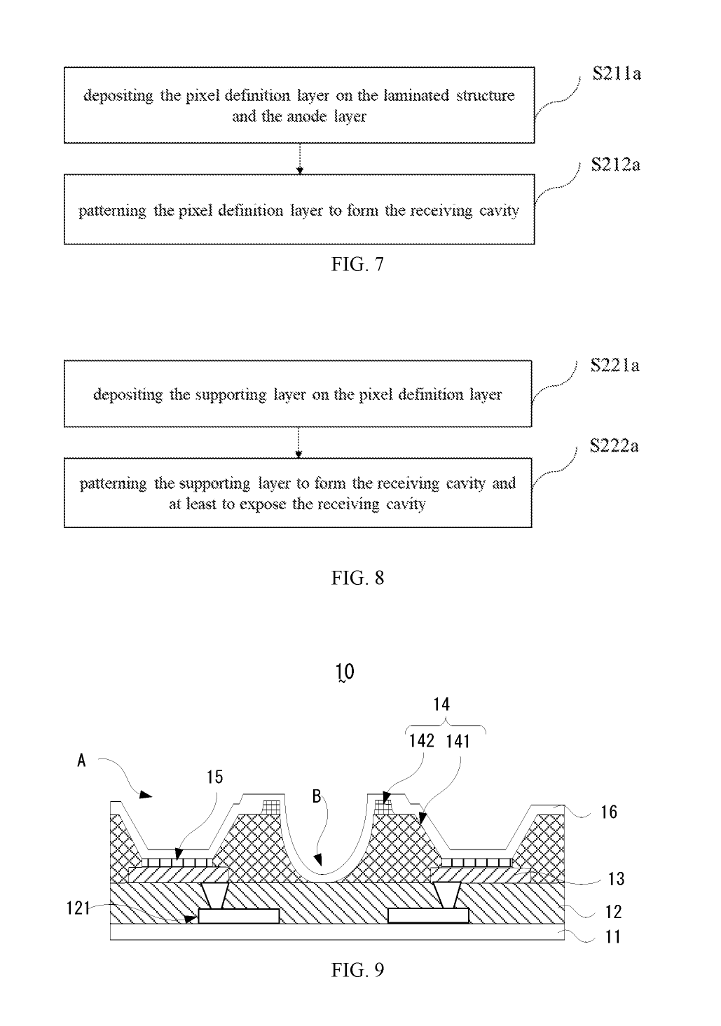

As shown in FIG. 7, step S21a further comprises the following sub-steps of:

S211a, depositing the PDL on the laminated structure and the anode layer.

S212a, patterning the PDL to form the receiving cavity.

Patterning the PDL by yellow process, particularly comprising the operations of pre-baking, exposure, development, curing, etc., to form the PDL with a receiving cavity structure. Wherein the PDL can be an organic photoresist layer.

S22a, preparing the supporting layer with the concave structure on the PDL, wherein the supporting layer does not cover the receiving cavity.

As shown in FIG. 8, step S22a further comprises the following sub-steps of:

S221a, depositing the supporting layer on the PDL.

After forming the PDL with the receiving cavity structure, disposing the supporting layer (PS) on the PDL, the supporting layer can also be an organic photoresist layer.

S222a, patterning the supporting layer to form the receiving cavity and at least to expose the receiving cavity.

Particularly, patterning the supporting layer between any two adjacent receiving cavities by yellow process, particularly comprising the operations of pre-baking, exposure, development, curing, etc., to form the concave structure. Wherein the concave structure can include but not limited to an arc, a circle and so on. In the embodiment, forming the concave structure eliminates the need for additional process and simplifies the operation.

And the concave structure in the above-described embodiment, disposed not only between any two adjacent receiving cavities, but also between two adjacent thin film transistors. It should be noted that the position of the concave structure does not need to be disposed on the same layer of adjacent receiving cavities or adjacent two thin film transistors.

S3, preparing an organic light emitting device in the receiving cavity.

Wherein, preparing the organic light emitting device on the PDL with the receiving cavity structure, particularly preparing the organic light emitting device by vapor deposition process in the receiving cavity.

S4, preparing a reflective cathode layer on the light emitting device and the photoresist layer.

After forming the organic light emitting device, the reflective cathode layer is further deposited on the organic light emitting device and the photoresist layer. In the case of forming an entire surface of the reflective cathode layer, a structure similar to that of a convex lens is formed in the above-described concave structure. Of course, the shape of the concave structure is not limited to an arc shape, a circular shape, or other shapes that can block light propagation in the pixel region, the present disclosure is not particularly limited. When the light emitted from the organic light emitting device is reflected by the reflection of the cathode layer with a similar convex lens, the light reflected from the reflective cathode layer is reflected back to the light emitting direction and attenuated, so that the light leakage phenomenon between the thin film transistor gap can be effectively prevented, and enhance the panel display quality.

In the above embodiment, by preparing the concave structure on the photoresist layer, and it can reflect the light from the reflective cathode layer back to the light emitting direction and attenuate; the light leakage phenomenon caused by the reflective cathode layer can be prevented, and enhance the panel display quality.

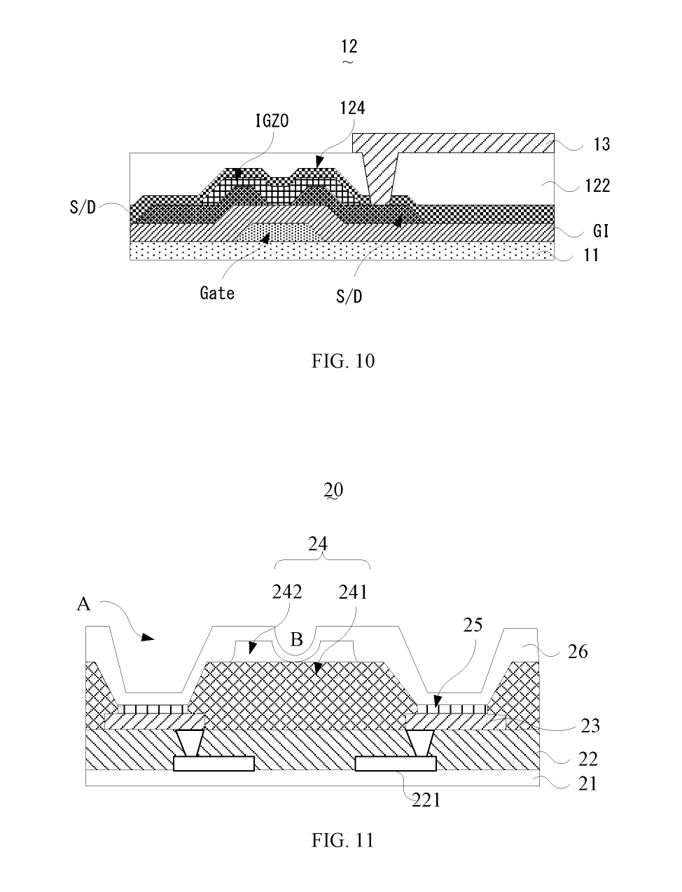

Referring to FIGS. 9, 10 and 11, FIG. 9 is a schematic structure diagram showing an embodiment of the array substrate of the present disclosure, FIG. 10 is a schematic structure diagram showing an embodiment of the laminated structure in the array substrate of the present disclosure, FIG. 11 is a schematic structure diagram showing another embodiment of the array substrate of the present disclosure. As shown in FIG. 9, the array substrate comprises: the substrate 11, the laminated structure 12, the anode layer 13, the photoresist layer 14, the organic light emitting device 15, and the reflective cathode layer 16.

Wherein the substrate 11 can be a transparent material, particularly can be any type of substrate such as glass, ceramic substrate or transparent plastic and so on, the present disclosure is not specifically limited thereto.

The laminated structure 12 is formed on the substrate 11, and the laminated structure further comprises: a plurality of thin film transistors 121 and the PLN 122, the specific structure can be found in FIG. 10, and the laminated structure listed in the present embodiment is merely an illustrative example and is not limited thereto, and other similar conversion structures are also applicable to the present disclosure and are not particularly limited thereto.

Wherein the thin film transistor 121 further comprises: The Gate electrode layer (Gate), the gate insulating layer (GI), the source electrode layer (S), the drain electrode layer (D) and the semiconductor oxide layer (IGZO), the semiconductor oxide layer (IGZO) covers the gate insulating layer (GI), the source electrode layer (S), and the drain electrode layer (D).

In addition, the laminated structure 12 further comprises the PAS 124, and the PAS 124 covers on the semiconductor oxide layer IGZO.

The PLN 122 is formed on the PAS 124.

The anode layer 13 covering on the laminated structure 12, particularly covering the

PLN 122 on the laminated structure 12.

The photoresist layer 14 is deposited on the anode layer 13 and the laminated structure 12, the photoresist layer 14 further comprises the receiving cavity A and the concave structure B. In a particular embodiment, the concave structure B of the photoresist layer 14 is divided into two cases: 1. the concave structure B is disposed on the PDL, 2. the concave structure B is disposed on the PDL. Referring to FIG. 11 a particularly configuration, and the particularly manufacturing method and process of the concave structure are described in detail in the above-mentioned manufacturing method, it will not be repeated herein.

The organic light emitting device 15 is disposed in the receiving cavity A.

The reflective cathode layer 16 is deposited on the organic light emitting device 15 and the photoresist layer 14.

In the above embodiment, by preparing the concave structure on the photoresist layer, the light reflected from the reflective cathode layer can be reflected back to the light emitting direction and attenuated, the light leakage phenomenon caused by the reflective cathode layer can be prevented, and enhance the panel display quality.

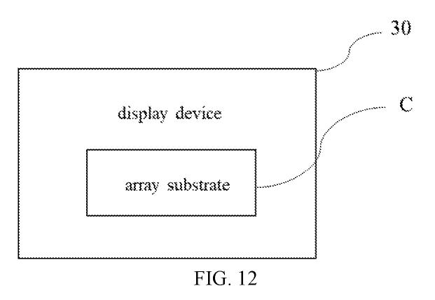

Referring to FIG. 12, FIG. 12 is a schematic structure diagram showing an embodiment of a display device of the present disclosure, the display device 30 comprises the array substrate C with any of the above-described structures, and the particularly embodiment of the array substrate C is described in the above embodiments, it will not be repeated herein.

In summary, one skilled in the art will readily appreciate that the present disclosure provides an array substrate and a method for manufacturing thereof, and a display device. By preparing the concave structure on the photoresist layer, the light reflected from the reflective cathode layer can be reflected back to the light emitting direction and attenuated, it can prevent the light leakage phenomenon caused by a reflective cathode layer and enhance panel display quality.

The embodiments described above are only embodiments of the present disclosure, not intended to limit the scope of the present disclosure, all utilize the present specification and drawings taken equivalent structures or equivalent process, or other direct or indirect application related technical fields shall fall within the scope of protection of the present disclosure.

What is claimed is:

1. A display device, wherein the display device comprises an array substrate, and the array substrate comprises:
a substrate;
a laminated structure, disposed on the substrate;
an anode layer, disposed on the laminated structure;
a photoresist layer, deposited on the anode layer and the laminated structure, the photoresist layer comprises a receiving cavity and a concave structure;
an organic light emitting device, disposed within the receiving cavity; and
a reflective cathode layer, deposited on the organic light emitting device and the photoresist layer;
wherein the laminated structure comprises a plurality of thin film transistors and a planarization layer;
the photoresist layer comprises a pixel definition layer and a supporting layer.

2. A method of manufacturing an array substrate, wherein the method comprises:
preparing a laminated structure and an anode layer on the substrate sequentially;
preparing a photoresist layer with a receiving cavity and a concave structure on the laminated structure and the anode layer;
preparing an organic light emitting device in the receiving cavity; and
preparing a reflective cathode layer on the organic light emitting device and the photoresist layer.

3. The method of manufacturing the array substrate according to claim 2, wherein preparing the photoresist layer with the receiving cavity and the concave structure on the laminated structure and the anode layer comprises:
preparing a pixel definition layer with the receiving cavity and the concave structure on the laminated structure and the anode layer; and
preparing a supporting layer on the pixel definition layer, wherein the supporting layer does not cover the receiving cavity and the concave structure.

4. The method of manufacturing the array substrate according to claim 3, wherein preparing the pixel definition layer with the receiving cavity and the concave structure on the laminated structure and the anode layer comprises:
depositing the pixel definition layer on the laminated structure and the anode layer;
patterning the pixel definition layer to form the receiving cavity and the concave structure; and
preparing the supporting layer on the pixel definition layer comprises:
depositing the supporting layer on the pixel definition layer; and
patterning the supporting layer to expose the receiving cavity and the concave structure at least.

5. The method of manufacturing the array substrate according to claim 2, wherein preparing the photoresist layer with the receiving cavity and the concave structure on the laminated structure and the anode layer comprises:
preparing a pixel definition layer with the receiving cavity on the laminated structure and the anode layer; and
preparing a supporting layer with the receiving cavity on the pixel definition layer, wherein the supporting layer does not cover the receiving cavity.

6. The method of manufacturing the array substrate according to claim 5, wherein preparing the pixel definition layer with the receiving cavity on the laminated structure and the anode layer comprises:
depositing the pixel definition layer on the laminated structure and the anode layer;
patterning the pixel definition layer to form the receiving cavity; and
preparing the supporting layer with the concave structure on the pixel definition layer comprises:
depositing the supporting layer on the pixel definition layer; and
patterning the supporting layer to form the concave structure and to expose the receiving cavity at least.

7. The method of manufacturing the array substrate according to claim 2, wherein each of the concave structures is disposed between two adjacent receiving cavities.

8. The method of manufacturing the array substrate according to claim 2, wherein preparing the laminated structure on the substrate sequentially comprises:
preparing a plurality of thin film transistors on the substrate; and
depositing a planarization layer on the thin film transistors.

9. The method of manufacturing the array substrate according to claim 8, wherein each of the concave structures is disposed between two adjacent thin film transistors.

10. An array substrate, wherein the array substrate comprises:
a substrate,
a laminated structure, disposed on the substrate;
an anode layer, disposed on the laminated structure;
a photoresist layer, deposited on the anode layer and the laminated structure, the photoresist layer comprises a receiving cavity and a concave structure;
an organic light emitting device, disposed within the receiving cavity; and
a reflective cathode layer, deposited on the organic light emitting device and the photoresist layer.
